(19) United States
(12) Patent Application Publication
(10) Pub. No.: US 2025/0167191 A1
(43) Pub. Date: May 22, 2025

(54) UTILIZING MEMORY CHIP THROUGH-SILICON VIAS FOR CONNECTING LOGIC CHIP TO SUBSTRATE

(71) Applicant: International Business Machines Corporation, Armonk, NY (US)

(72) Inventors: Robert K. Montoye, New York, NY (US); Kyu-hyoun Kim, Chappaqua, NY (US); Todd Edward Takken, Brewster, NY (US)

(21) Appl. No.: 18/518,179

(22) Filed: Nov. 22, 2023

(51) Int. Cl. H01L 25/18; H01L 23/00; H01L 23/48; H01L 25/065

(52) U.S. Cl. CPC H01L 25/18; H01L 23/481; H01L 24/16; H01L 25/0657; H01L 2224/16145; H01L 2225/06513; H01L 2225/06541; H01L 2924/1431; H01L 2924/1438

(57) ABSTRACT

An integrated circuit device with a chip stacking architecture that is effective in cooling a higher-power logic chip as well as effective in providing power and signal connections and high bandwidth to the logic chip. The integrated circuit device includes a chip stacking architecture that includes a substrate, one or more memory chips stacked on top of the substrate and a logic chip stacked on top of the one or more memory chips, where the logic chip communicates with the substrate via through-silicon vias located in the memory chip(s). A portion of the through-silicon vias in the memory chip(s) are electronically disconnected from a specific memory chip and therefore are able to be used to enable the logic chip to communicate with the substrate.

### TECHNICAL FIELD

The present disclosure relates generally to chip stacking architectures, and more particularly to a chip stacking architecture with a logic chip that communicates with the substrate using through-silicon vias located in the memory chip.

### BACKGROUND

Chip stacking is a method of attaching integrated circuiits (commonly referred to as simply “chips”) vertically to increase efficiency and make better use of the available space. An integrated circuit is a set of electronic circuits on one small flat piece (or “chip”) of semiconductor material, usually silicon. The vertical assemblies can involve chips of the same size or different sizes. When the chips are different in size, they are stacked offset one on top of another, usually three or four die (small block of semiconducting material on which a given functional circuit is fabricated). They are connected to each other typically by a film adhesive, and electrically, by wire bonding or flip chip methods. The stack is then connected to the substrate in the same manner. If the chips are the same size, invariably they have a staggered arrangement.

Currently, chip stacking typically consists of stacked high bandwidth memory (HBM) chips, packaged on a common substrate next to a logic chip. HBM is a high-speed computer memory interface for 3D-stacked synchronous dynamic random-access memory. It is used in conjunction with high-performance graphics accelerators, network devices, high-performance datacenter AI (artificial intelligence) ASICs (application specific integrated circuits), FPGAs (field programmable gate arrays), etc.

HBM achieves higher bandwidth while using less power by stacking up to eight DRAM (dynamic random-access memory) dies and an optional base die which can include buffer circuitry and test logic. The stack is often connected to a memory controller on a GPU (graphic processing unit) or a CPU (central processing unit) through a substrate, such as a silicon interposer. Alternatively, the memory die could be stacked directly on the CPU or GPU chip. Within the stack, the die are vertically interconnected by through-silicon vias (TSVs) and microbumps.

As discussed above, chip stacking typically consists of stacked HBM chips, packaged on a common substrate next to a logic chip. In such an architecture, heat can be evacuated from the top of the memory stack without overheating the chips located at the bottom of the memory stack because the memory chips produce relatively little heat. In such cases, where the logic chip is located on the substrate besides the stack of memory chips, the bandwidth is constrained by the limited wiring capacity in the substrate. Higher memory bandwidth can be obtained by placing the logic and memory chips in the same vertical stack with the memory chips located on top of the logic chip. With the memory chips being located on top of the logic chip, the memory chips serve as a thermal insulator limiting the amount of heat that a top-contact cooling structure can remove from the bottom located logic chip. In addition to thermal difficulties, an arrangement with the memory chips stacked on top of the logic chip requires the logic chip designer to include through-silicon vias (TSVs) in the logic chip in order to pass power and signal connections from the logic chip both upwards to the memory chips and downwards to the interconnect substrate. If the logic chip was to be a high-power density processor using linewidth chip fabrication technology, then there would be a high cost to reserving space in the logic chip for TSVs. Not only would there be a large number of logic circuits lost for every TSV added to the logic chip, but such a design would also require a custom logic chip design that would be different from the current standard logic chip.

As a result, currently designed chip stacking architectures are not effective in cooling a higher-power logic chip as well as effectively providing power and signal connections and high bandwidth to the logic chip.

### SUMMARY

In one embodiment of the present disclosure, an integrated circuit device comprises a substrate and one or more memory chips stacked on top of the substrate. The integrated circuit device further comprises a logic chip stacked on top of the one or more memory chips, where the logic chip communicates with the substrate via through-silicon vias located in the one or more memory chips.

Additionally, in one embodiment of the present disclosure, the through-silicon vias are utilized for power connections.

Furthermore, in one embodiment of the present disclosure, the through-silicon vias are utilized for signaling connections.

Additionally, in one embodiment of the present disclosure, the one or more memory chips correspond to high bandwidth memory chips.

Furthermore, in one embodiment of the present disclosure, a first portion of the through-silicon vias terminate on one of the one or more memory chips.

Additionally, in one embodiment of the present disclosure, the first portion of the through-silicon vias are used to communicate with the one of the one or more memory chips.

Furthermore, in one embodiment of the present disclosure, a second portion of the through-silicon vias are electronically disconnected from a specific memory chip of the one or more memory chips.

Additionally, in one embodiment of the present disclosure, the second portion of the through-silicon vias are used for enabling the logic chip to communicate with the substrate.

Furthermore, in one embodiment of the present disclosure, the logic chip comprises a processor.

Additionally, in one embodiment of the present disclosure, the logic chip comprises a buffer.

Furthermore, in one embodiment of the present disclosure, the logic chip is stacked on top of the one or more memory chips via decoupling capacitors.

Additionally, in one embodiment of the present disclosure, the logic chip is stacked on top of the one or more memory chips via a voltage regulator.

Furthermore, in one embodiment of the present disclosure, the one or more memory chips are stacked on top of the substrate via a silicon spreader.

Additionally, in one embodiment of the present disclosure, a first portion of the through-silicon vias are connected to a first core logic domain within the one or more memory chips at a first voltage level. Furthermore, in one embodiment of the present disclosure, a second portion of the through-silicon vias are connected to a second core logic domain within the one or more memory chips at a second voltage level, where the second voltage level is higher than the first voltage level.

Furthermore, in one embodiment of the present disclosure, the logic chip comprises a step-down switched capacitor power converter circuit.

Additionally, in one embodiment of the present disclosure, the step-down switched capacitor power converter circuit corresponds to a 2:1 step-down converter.

Furthermore, in one embodiment of the present disclosure, the step-down switched capacitor power converter circuit produces a regulated voltage that is at a lower voltage level than a voltage level of the one or more memory chips.

Additionally, in one embodiment of the present disclosure, a portion of contacts of the through-silicon vias in the one or more memory chips are connected to the substrate using a redistribution layer process.

Furthermore, in one embodiment of the present disclosure, the redistribution layer process is used to expand a contact pitch.

Additionally, in one embodiment of the present disclosure, one of the one or more memory chips is used as a quad-level cell flash memory.

Accordingly, embodiments of the present disclosure provide a high-performance, cost-effective chip stacking architecture while cools a high-power logic chip, provides power and signal connections to the logic chip through the memory chips and provides high bandwidth between the logic chip and the memory chips.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an embodiment of the present disclosure of an integrated circuit device fabricated using chip stacking;

FIG. 2 illustrates the utilization of through-silicon vias in the memory chips of the integrated circuit device in accordance with an embodiment of the present disclosure; and

FIG. 3 illustrates an alternative embodiment of the present disclosure of the integrated circuit device fabricated using chip stacking.

### DETAILED DESCRIPTION

In one embodiment of the present disclosure, an integrated circuit device comprises a substrate and one or more memory chips stacked on top of the substrate. The integrated circuit device further comprises a logic chip stacked on top of the one or more memory chips, where the logic chip communicates with the substrate via through-silicon vias located in the one or more memory chips.

In this manner, a high-performance, cost-effective chip stacking architecture is provided which cools a high-power logic chip, provides power and signal connections to the logic chip through the memory chips and provides high bandwidth between the logic chip and the memory chips.

Additionally, in one embodiment of the present disclosure, the through-silicon vias are utilized for power connections.

In this manner, power connections are provided to the logic chip through the memory chips.

Furthermore, in one embodiment of the present disclosure, the through-silicon vias are utilized for signaling connections.

In this manner, signaling connections are provided to the logic chip through the memory chips.

Additionally, in one embodiment of the present disclosure, the one or more memory chips correspond to high bandwidth memory chips.

In this manner, the memory chips provide high bandwidth and low power consumption.

Furthermore, in one embodiment of the present disclosure, a first portion of the through-silicon vias terminate on one of the one or more memory chips.

In this manner, communication can be established with the memory chip upon which the through-silicon vias terminate.

Additionally, in one embodiment of the present disclosure, the first portion of the through-silicon vias are used to communicate with the one of the one or more memory chips.

In this manner, communication with the memory chips can be established.

Furthermore, in one embodiment of the present disclosure, a second portion of the through-silicon vias are electronically disconnected from a specific memory chip of the one or more memory chips.

In this manner, communication between the logic chip and the substrate can be established.

Additionally, in one embodiment of the present disclosure, the second portion of the through-silicon vias are used for enabling the logic chip to communicate with the substrate.

In this manner, the logic chip is able to communicate with the substrate via a portion of the through-silicon vias in the memory chips.

Furthermore, in one embodiment of the present disclosure, the logic chip comprises a processor.

In this manner, the processor to substrate power and signal connections may be established.

Additionally, in one embodiment of the present disclosure, the logic chip comprises a buffer.

In this manner, the current capacity of the signal is boosted so as to be able to drive a load.

Furthermore, in one embodiment of the present disclosure, the logic chip is stacked on top of the one or more memory chips via decoupling capacitors.

In this manner, one part of a circuit may be isolated or decoupled from another.

Additionally, in one embodiment of the present disclosure, the logic chip is stacked on top of the one or more memory chips via a voltage regulator.

In this manner, a steady constant voltage supply is ensured through all operational conditions.

Furthermore, in one embodiment of the present disclosure, the one or more memory chips are stacked on top of the substrate via a silicon spreader.

In this manner, the wetting, spreading, and penetration of chemicals is improved.

Additionally, in one embodiment of the present disclosure, a first portion of the through-silicon vias are connected to a first core logic domain within the one or more memory chips at a first voltage level. Furthermore, in one embodiment of the present disclosure, a second portion of the through-silicon vias are connected to a second core logic domain within the one or more memory chips at a second voltage level, where the second voltage level is higher than the first voltage level.

In this manner, different voltage levels may be utilized for powering different elements.

Furthermore, in one embodiment of the present disclosure, the logic chip comprises a step-down switched capacitor power converter circuit.

In this manner, a high voltage power is converted into a lower voltage power.

Additionally, in one embodiment of the present disclosure, the step-down switched capacitor power converter circuit corresponds to a 2:1 step-down converter.

In this manner, the voltage level may be converted into a lower voltage power by a factor of two.

Furthermore, in one embodiment of the present disclosure, the step-down switched capacitor power converter circuit produces a regulated voltage that is at a lower voltage level than a voltage level of the one or more memory chips.

In this manner, a voltage level is produced that is lower than the voltage level of the memory chips.

Additionally, in one embodiment of the present disclosure, a portion of contacts of the through-silicon vias in the one or more memory chips are connected to the substrate using a redistribution layer process.

In this manner, an extra metal layer is established that makes its I/O pads available in other locations of the substrate for better access to the pads where necessary.

Furthermore, in one embodiment of the present disclosure, the redistribution layer process is used to expand a contact pitch.

In this manner, the distance from the center of one contact to the center of the next contact on the substrate is expanded.

Additionally, in one embodiment of the present disclosure, one of the one or more memory chips is used as a quad-level cell flash memory.

In this manner, 4 bits of data per memory cell can be stored.

As stated above, currently, chip stacking typically consists of stacked high bandwidth memory (HBM) chips, packaged on a common substrate next to a logic chip. HBM is a high-speed computer memory interface for 3D-stacked synchronous dynamic random-access memory. It is used in conjunction with high-performance graphics accelerators, network devices, high-performance datacenter AI (artificial intelligence) ASICs (application specific integrated circuits), FPGAs (field programmable gate arrays), etc.

HBM achieves higher bandwidth while using less power by stacking up to eight DRAM (dynamic random-access memory) dies and an optional base die which can include buffer circuitry and test logic. The stack is often connected to a memory controller on a GPU (graphic processing unit) or a CPU (central processing unit) through a substrate, such as a silicon interposer. Alternatively, the memory die could be stacked directly on the CPU or GPU chip. Within the stack, the die are vertically interconnected by through-silicon vias (TSVs) and microbumps.

As discussed above, chip stacking typically consists of stacked HBM chips, packaged on a common substrate next to a logic chip. In such an architecture, heat can be evacuated from the top of the memory stack without overheating the chips located at the bottom of the memory stack because the memory chips produce relatively little heat. In such cases, where the logic chip is located on the substrate besides the stack of memory chips, the bandwidth is constrained by the limited wiring capacity in the substrate. Higher memory bandwidth can be obtained by placing the logic and memory chips in the same vertical stack with the memory chips located on top of the logic chip. With the memory chips being located on top of the logic chip, the memory chips serve as a thermal insulator limiting the amount of heat that a top-contact cooling structure can remove from the bottom located logic chip. In addition to thermal difficulties, an arrangement with the memory chips stacked on top of the logic chip requires the logic chip designer to include through-silicon vias (TSVs) in the logic chip in order to pass power and signal connections from the logic chip both upwards to the memory chips and downwards to the interconnect substrate. If the logic chip was to be a high-power density processor using linewidth chip fabrication technology, then there would be a high cost to reserving space in the logic chip for TSVs. Not only would there be a large number of logic circuits lost for every TSV added to the logic chip, but such a design would also require a custom logic chip design that would be different from the current standard logic chip.

As a result, currently designed chip stacking architectures are not effective in cooling a higher-power logic chip as well as effectively providing power and signal connections and high bandwidth to the logic chip.

The embodiments of the present disclosure provide a means for a chip stacking architecture that is effective in cooling a higher-power logic chip as well as effectively providing power and signal connections and high bandwidth to the logic chip. In one embodiment, an integrated circuit device includes a chip stacking architecture that includes a substrate, one or more memory chips stacked on top of the substrate and a logic chip stacked on top of the one or more memory chips, where the logic chip communicates with the substrate via through-silicon vias located in the memory chip(s). A portion of the through-silicon vias in the memory chip(s) are electronically disconnected from a specific memory chip and therefore are able to be used to enable the logic chip to communicate with the substrate. In this manner, such a chip stacking architecture provides a high-performance, cost-effective chip stacking architecture, which cools a high-power logic chip, provides power and signal connections to the logic chip through the stack of one or more memory chips and provides high bandwidth between the logic chip and the memory chip(s). A further description of these and other features will be provided below.

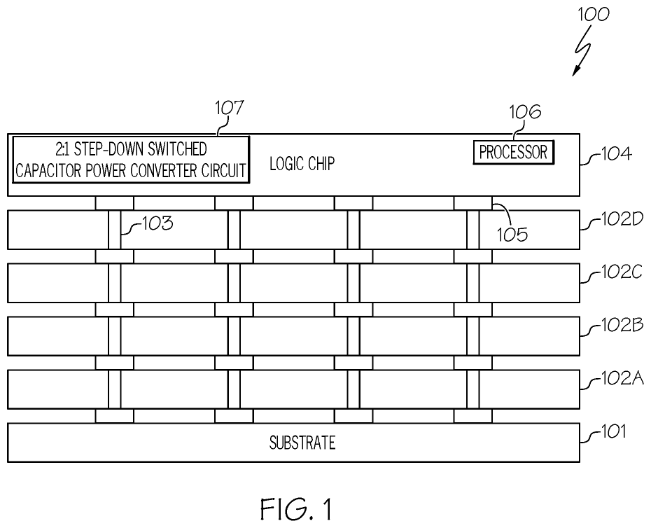

Referring now to the Figures in detail, FIG. 1 illustrates an embodiment of the present disclosure of an integrated circuit device 100 fabricated using chip stacking. In one embodiment, integrated circuit 100 is a 3D integrated circuit. In one embodiment, integrated circuit device 100 includes a substrate 101 and memory chips 102A-102D stacked on top of substrate 101. Memory chips 102A-102D may collectively or individually be referred to as memory chips 102 or memory chip 102, respectively. While FIG. 1 illustrates four memory chips 102, integrated circuit device 100 may include any number of stacked memory chips 102. For example, integrated circuit device 100 may include four, eight or twelve memory chips 102. Examples of memory chips 102 include, but are not limited to, dynamic random-access memory (DRAM), 3D vertical NAND, 3D-stacked synchronous dynamic random-access memory (SDRAM), etc. An example of substrate 101 is a silicon interposer (electrical interface routing between one socket or connection to another).

In one embodiment, such memory chips 102 correspond to high bandwidth memory (HBM) chips, which utilize a 3D stacking technology, which enables various layers of memory chips 102 to be stacked on top of each other by vertical channels, referred to herein as through-silicon vias 103 (“TSVs”).

TSVs 103, as used herein, refer to vertical electrical connections (vias) that pass completely through the stack of memory chips 102. TSVs 103 are high-performance interconnect techniques used as an alternative to wire-bond and flip chips to create 3D packages and 3D integrated circuits.

In one embodiment, as shown in FIG. 1, memory chips 102 are bonded to each other as well as to substrate 101 and logic chip 104 via microbumps 105. Logic chip 104, as used herein, refers to a chip designed to operate on data. Examples of logic chip 104 include, but are not limited to, a central processing unit, a graphic processing unit, etc. Microbumps 105, as used herein, refer to the bonding medium supporting power and signaling between the top and bottom chips.

As discussed above, currently designed chip stacking architectures are not effective in cooling a higher-power logic chip as well as effectively providing power and signal connections and high bandwidth to the logic chip. Embodiments of the present disclosure provide a means for a chip stacking architecture, such as illustrated in FIG. 1, that is effective in cooling a higher-power logic chip (e.g., logic chip 104) as well as effective in providing power and signal connections and high bandwidth to the logic chip (e.g., logic chip 104) as discussed below.

In one embodiment, as discussed above, memory chips 102 correspond to high bandwidth memory (HBM) chips. In such an embodiment, memory chips 102 include hundreds to thousands of TSVs 103 arranged in logical quadrants. In one embodiment, in a given memory chip 102, a portion (e.g., one-fourth) of the signal TSVs 103 terminate on that specific memory chip 102 (e.g., memory chip 102A) and are used to communicate with that memory chip 102 (e.g., memory chip 102A). A “signal TSV 103,” as used herein, refers to a TSV that transmits signals. The other portion (e.g., three quarters) of the signal TSVs 103 (e.g., 750 TSVs 103) are electrically disconnected from that specific memory chip 102 (e.g., memory chip 102A). In one embodiment, such locally unconnected signal TSVs 103 in an HBM memory chip 102 are used to pass general nonmemory signals between logic chip 104, such as a processor 106 of logic chip 104, and substrate 101. That is, such locally unconnected signal TSVs 103 are used for enabling logic chip 104, such as processor 106, to communicate with substrate 101. Examples of processor 106 include Intel Xeon Phi® processor, AI (artificial intelligence) processor, Sapphire Rapids Xeon SP processor, etc.

In one embodiment, memory chip TSVs 103 supply power to logic chip 104. In one embodiment, memory chip 102 has hundreds or thousands of power TSVs 103. A “power TSV 103,” as used herein, refers to a TSV that transmits power. In one embodiment, a first portion of power TSVs 103 are connected to a core logic domain within memory chip 102 at a first voltage level, such as 1.2 V. A second portion of power TSVs 103 are connected to a core logic domain within memory chip 102 at a second voltage level, which is higher than the first voltage level. In one embodiment, the second portion of TSVs 103 is smaller than the first portion of TSVs 103. In this manner, different voltage levels may be utilized for powering different elements.

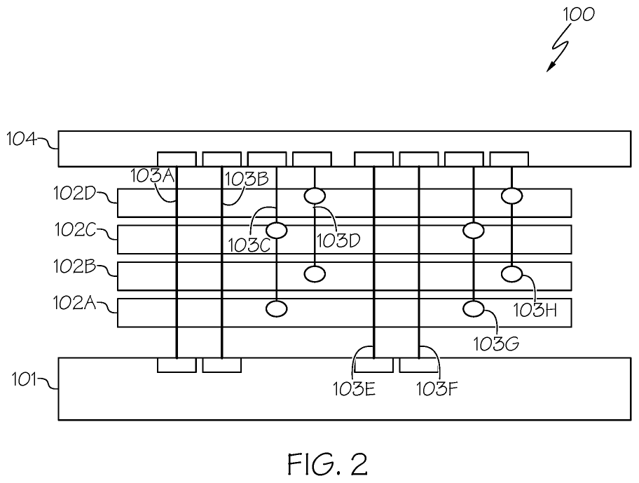

An illustration of TSVs 103 in memory chips 102 being used to communicate with memory chips 102 as well as enabling logic chip 104 to communicate with substrate 101 is provided in FIG. 2.

Referring to FIG. 2, FIG. 2 illustrates the utilization of TSVs 103 in memory chips 102 of integrated circuit device 100 in accordance with an embodiment of the present disclosure.

As illustrated in FIG. 2, in conjunction with FIG. 1, a portion of TSVs 103, such as signal or power TSVs 103, terminate on a specific memory chip 102 (e.g., memory chip 102A) and are used to communicate with memory chip 102 (e.g., memory chip 102A). For example, TSVs 103C, 103G terminate on memory chip 102A and are used to communicate with memory chip 102A. In another example, TSVs 103D, 103H terminate on memory chip 102B and are used to communicate with memory chip 102B.

Furthermore, a portion of TSVs 103, such as signal or power TSVs, are electrically disconnected from memory chips 102 and are used by logic chip 104 to communicate with substrate 101. For example, TSVs 103A, 103B, 103E, and 103F are used for connecting logic chip 104 and substrate 101. TSVs 103A-103H may collectively or individually be referred to as TSVs 103 or TSV 103, respectively.

While FIG. 2 illustrates a certain number of TSVs 103 being used to communicate with memory chip 102 or enable communication between logic chip 104 and substrate 101, it is noted that the embodiments of the present disclosure may utilize any number of TSVs 103 for such communication.

Returning to FIG. 1, in one embodiment, logic chip 104 includes a step-down switched capacitor power converter circuit 107. As a result, a high voltage power is converted into a lower voltage power. In one embodiment, step-down switched capacitor power converter circuit 107 corresponds to a 2:1 step-down switched capacitor power convert circuit. As a result, the voltage level may be converted into a lower voltage power by a factor of two. Examples of such a step-down switched capacitor power converter circuit 107 include, but are not limited to, LM3353 converter, LM2770 converter, etc.

In one embodiment, such a step-down switched capacitor power converter circuit 107 provides a roughly 0.6 V core voltage logic domain to logic chip 104 using the 1.2 V power TSVs 103. In one embodiment, the higher-voltage power TSVs 103 are used for phased locked loops, input/output (I/O) drivers or other functions in logic chip 104 with no power conversion. In one embodiment, some of memory chip's 102 unconnected signal TSVs 103 are used to provide additional voltages to logic chip 104 instead of being used for signal connections.

In one embodiment, step-down switched capacitor power converter circuit 107 produces a regulated voltage that is at a lower voltage level than a voltage level of memory chips 102. In this manner, a voltage level is produced that is lower than the voltage level of memory chips 102.

In one embodiment, the lateral pitch (minimum center-to-center distance between interconnect lines) of memory chip TSVs 103 is smaller in comparison to the contact pitches (the distance from the center of one contact to the center of the next contact) on substrate 101. A contact, as used herein, refers to a tiny and distinct structure that forms an electrical pathway, such as between a first interconnect layer and a transistor. In such an embodiment, the contacts of the bottom located TSVs 103, such as in memory chip 102A, are connected to substrate 101 below the stack. In one embodiment, the contacts of such TSVs 103 are connected to substrate 101 below the stack using a redistribution layer process, which is used to expand the contact pitch. A redistribution layer, as used herein, refers to an extra metal layer that makes its I/O pads available in other locations of substrate 101 for better access to the pads where necessary.

Alternatively, in one embodiment, fine pitch build-up layers are added to the top of substrate 101 to address the lateral pitch of memory chip TSVs 103 being smaller in comparison to the contact pitches on substrate 101

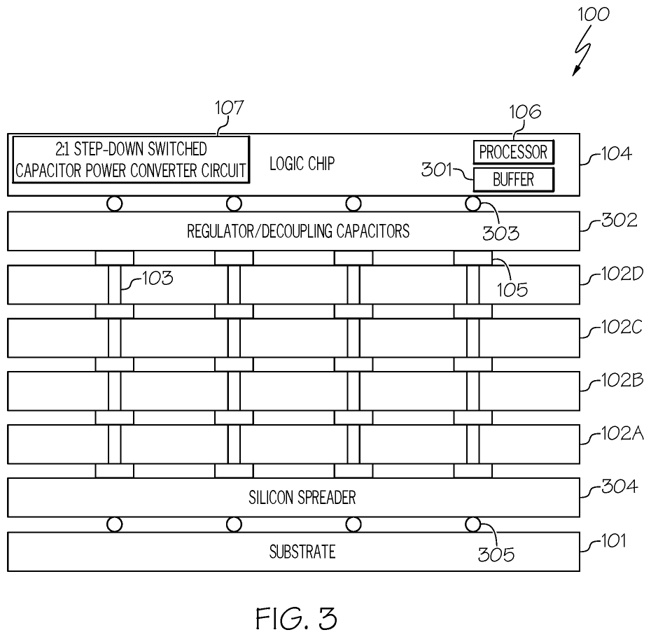

An alternative embodiment of integrated circuit device 100 is shown in FIG. 3.

Referring to FIG. 3, FIG. 3 illustrates an alternative embodiment of integrated circuit device 100 fabricated using chip stacking in accordance with an embodiment of the present disclosure.

As shown in FIG. 3, integrated circuit device 100 includes a logic chip 104 that includes a buffer 301. A buffer 301, as used herein, refers to a logic gate that has one input and its output follows the same logic state as the input. As a result, buffer 301 is used as a delay element. In one embodiment, buffer 301 is used to boost the current capacity of the signal so as to be able to drive a load.

Furthermore, as illustrated in FIG. 3, logic chip 104 is now connected to element 302, which corresponds to a regulator or decoupling capacitors, via interconnects 303. A “regulator,” as used herein, refers to a device that maintains a designated characteristic, such as a voltage level. For example, the regulator may correspond to a voltage regulator, which ensures a steady constant voltage supply through all operational conditions. Examples of such voltage regulators include linear voltage regulators (e.g., series voltage regulators) and switching voltage regulators (e.g., step-up voltage regulators, step-down voltage regulators, a boost converter).

In one embodiment, the regulator of element 302 is configured to regulate from a voltage level of memory chips 102 to the voltage level of logic chip 104.

“Decoupling capacitors,” as used herein, refer to capacitors that are used to isolate or decouple one part of a circuit from another.

“Interconnects 303,” as used herein, refer to structures that connect two or more circuit elements together electrically.

Furthermore, as illustrated in FIG. 3, stacks of memory chips 102 are stacked on top of substrate 101 via a silicon spreader 304. In particular, the bottom memory chip, memory chip 102A, of the stacked memory chips 102, is electrically connected to silicon spreader 304 via microbumps 105. Silicon spreader 304, as used herein, refers to a wetting agent developed to improve the wetting, spreading, and penetration of chemicals. Examples of silicon spreader 304 include, but are not limited to, Silicon Spreader FX SP 220, Katyayani Catalyser Silicon Super Spreader, etc.

Additionally, as illustrated in FIG. 3, silicon spreader 304 is electrically connected to substrate 101 via interconnects 305, which are structurally similar to interconnects 303.

Furthermore, in one embodiment, one of memory chips 102, such as memory chip 102A, may be used as a quad-level cell flash memory. A quad-level cell flash memory, as used herein, refers to a form of NAND flash memory that can store up to 4 bits of data per memory cell.

In this manner, such a chip stacking architecture provides a high-performance, cost-effective chip stacking architecture, which cools a high-power logic chip, provides power and signal connections to the logic chip through the stack of one or more memory chips and provides high bandwidth between the logic chip and the memory chip(s).

Furthermore, the principles of the present disclosure improve the technology or technical field involving chip stacking architectures.

As discussed above, currently, chip stacking typically consists of stacked high bandwidth memory (HBM) chips, packaged on a common substrate next to a logic chip. HBM is a high-speed computer memory interface for 3D-stacked synchronous dynamic random-access memory. It is used in conjunction with high-performance graphics accelerators, network devices, high-performance datacenter AI (artificial intelligence) ASICs (application specific integrated circuits), FPGAs (field programmable gate arrays), etc. HBM achieves higher bandwidth while using less power by stacking up to eight DRAM (dynamic random-access memory) dies and an optional base die which can include buffer circuitry and test logic. The stack is often connected to a memory controller on a GPU (graphic processing unit) or a CPU (central processing unit) through a substrate, such as a silicon interposer. Alternatively, the memory die could be stacked directly on the CPU or GPU chip. Within the stack, the die are vertically interconnected by through-silicon vias (TSVs) and microbumps. As discussed above, chip stacking typically consists of stacked HBM chips, packaged on a common substrate next to a logic chip. In such an architecture, heat can be evacuated from the top of the memory stack without overheating the chips located at the bottom of the memory stack because the memory chips produce relatively little heat. In such cases, where the logic chip is located on the substrate besides the stack of memory chips, the bandwidth is constrained by the limited wiring capacity in the substrate. Higher memory bandwidth can be obtained by placing the logic and memory chips in the same vertical stack with the memory chips located on top of the logic chip. With the memory chips being located on top of the logic chip, the memory chips serve as a thermal insulator limiting the amount of heat that a top-contact cooling structure can remove from the bottom located logic chip. In addition to thermal difficulties, an arrangement with the memory chips stacked on top of the logic chip requires the logic chip designer to include through-silicon vias (TSVs) in the logic chip in order to pass power and signal connections from the logic chip both upwards to the memory chips and downwards to the interconnect substrate. If the logic chip was to be a high-power density processor using linewidth chip fabrication technology, then there would be a high cost to reserving space in the logic chip for TSVs. Not only would there be a large number of logic circuits lost for every TSV added to the logic chip, but such a design would also require a custom logic chip design that would be different from the current standard logic chip. As a result, currently designed chip stacking architectures are not effective in cooling a higher-power logic chip as well as effectively providing power and signal connections and high bandwidth to the logic chip.

Embodiments of the present disclosure improve such technology by fabricating an integrated circuit device with a chip stacking architecture that includes a substrate, one or more memory chips stacked on top of the substrate and a logic chip stacked on top of the one or more memory chips, where the logic chip communicates with the substrate via through-silicon vias located in the memory chip(s). A portion of the through-silicon vias in the memory chip(s) are electronically disconnected from a specific memory chip and therefore are able to be used to enable the logic chip to communicate with the substrate. In this manner, such a chip stacking architecture provides a high-performance, cost-effective chip stacking architecture, which cools a high-power logic chip, provides power and signal connections to the logic chip through the stack of one or more memory chips and provides high bandwidth between the logic chip and the memory chip(s). Furthermore, in this manner, there is an improvement in the technical field involving chip stacking architectures.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An integrated circuit device comprising:
a substrate;
one or more memory chips stacked on top of said substrate; and
a logic chip stacked on top of said one or more memory chips;
wherein said logic chip communicates with said substrate via through-silicon vias located in said one or more memory chips.

2. The integrated circuit device as recited in claim 1, wherein said through-silicon vias are utilized for power connections.

3. The integrated circuit device as recited in claim 1, wherein said through-silicon vias are utilized for signaling connections.

4. The integrated circuit device as recited in claim 1, wherein said one or more memory chips correspond to high bandwidth memory chips.

5. The integrated circuit device as recited in claim 1, wherein a first portion of said through-silicon vias terminate on one of said one or more memory chips.

6. The integrated circuit device as recited in claim 5, wherein said first portion of said through-silicon vias are used to communicate with said one of said one or more memory chips.

7. The integrated circuit device as recited in claim 1, wherein a second portion of said through-silicon vias are electronically disconnected from a specific memory chip of said one or more memory chips.

8. The integrated circuit device as recited in claim 7, wherein said second portion of said through-silicon vias are used for enabling said logic chip to communicate with said substrate.

9. The integrated circuit device as recited in claim 1, wherein said logic chip comprises a processor.

10. The integrated circuit device as recited in claim 1, wherein said logic chip comprises a buffer.

11. The integrated circuit device as recited in claim 1, wherein said logic chip is stacked on top of said one or more memory chips via decoupling capacitors.

12. The integrated circuit device as recited in claim 1, wherein said logic chip is stacked on top of said one or more memory chips via a voltage regulator.

13. The integrated circuit device as recited in claim 1, wherein said one or more memory chips are stacked on top of said substrate via a silicon spreader.

14. The integrated circuit device as recited in claim 1, wherein a first portion of said through-silicon vias are connected to a first core logic domain within said one or more memory chips at a first voltage level, wherein a second portion of said through-silicon vias are connected to a second core logic domain within said one or more memory chips at a second voltage level, wherein said second voltage level is higher than said first voltage level.

15. The integrated circuit device as recited in claim 14, wherein said logic chip comprises a step-down switched capacitor power converter circuit.

16. The integrated circuit device as recited in claim 15, wherein said step-down switched capacitor power converter circuit corresponds to a 2:1 step-down converter.

17. The integrated circuit device as recited in claim 15, wherein said step-down switched capacitor power converter circuit produces a regulated voltage that is at a lower voltage level than a voltage level of said one or more memory chips.

18. The integrated circuit device as recited in claim 1, wherein a portion of contacts of said through-silicon vias in said one or more memory chips are connected to said substrate using a redistribution layer process.

19. The integrated circuit device as recited in claim 18, wherein said redistribution layer process is used to expand a contact pitch.

20. The integrated circuit device as recited in claim 1, wherein one of said one or more memory chips is used as a quad-level cell flash memory.
